(19) United States
(12) Patent Application Publication
(10) Pub. No.: US 2017/0314120 A1
(43) Pub. Date: Nov. 2, 2017

(54) MATERIAL DEPOSITION ARRANGEMENT, A VACUUM DEPOSITION SYSTEM AND METHOD FOR DEPOSITING MATERIAL

(71) Applicant: Applied Materials, Inc., Santa Clara, CA (US)

(72) Inventors: Thomas GEBELE, Freigericht (DE); Uwe SCHÜßLER, Aschaffenburg (DE); Jose Manuel DIEGUEZ-CAMPO, Hanau (DE); Andreas LOPP, Freigericht (DE)

(73) Assignee: Applied Materials, Inc., Santa Clara, CA (US)

(21) Appl. No.: 15/531,693

(22) PCT Filed: Dec. 17, 2014
(86) PCT No.: PCT/EP2014/078299

§ 371 Date: May 30, 2017

(51) Int. Cl. C23C 14/24; C23C 14/04; H01L 51/00

(52) U.S. Cl. CPC C23C 14/243; H01L 51/0011; C23C 14/042; H01L 51/001

(57) ABSTRACT

A material deposition arrangement for depositing evaporated material on a substrate in a vacuum chamber is described. The material deposition arrangement includes a crucible for providing material to be evaporated; a linear distribution pipe in fluid communication with the crucible; and a plurality of nozzles in the distribution pipe for guiding the evaporated material into the vacuum chamber. Each nozzle may have a nozzle inlet for receiving the evaporated material, a nozzle outlet for releasing the evaporated material to the vacuum chamber, and a nozzle passage between the nozzle inlet and the nozzle outlet. The nozzle passage of at least one of the plurality of nozzles includes a first section having a first length and a first size, and a second having a second length and a second size. The ratio of the second size to the first size is between 2 and 10.

### TECHNICAL FIELD OF THE INVENTION

Embodiments of the present invention relate to a material deposition arrangement, a vacuum deposition system and a method for depositing material on a substrate. Embodiments of the present invention particularly relate to a material deposition arrangement including a vacuum chamber, and a method for depositing a material on a substrate in a vacuum chamber.

### BACKGROUND OF THE INVENTION

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays because OLED pixels directly emit light and do not use a back light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in a manner to form a matrix display panel having individually energizable pixels. The OLED is generally placed between two glass panels, and the edges of the glass panels are sealed to encapsulate the OLED therein.

There are many challenges encountered in the manufacture of such display devices. OLED displays or OLED lighting applications include a stack of several organic materials, which are for example evaporated in vacuum. The organic materials are deposited in a subsequent manner through shadow masks. For the fabrication of OLED stacks with high efficiency, the co-deposition or co-evaporation of two or more materials, e.g. host and dopant, leading to mixed/doped layers is desired. Further, it has to be considered that there are several process conditions for the evaporation of the very sensitive organic materials.

For depositing the material on a substrate, the material is heated until the material evaporates. Pipes guide the evaporated material to the substrates through outlets or nozzles. In the past years, the precision of the deposition process has been increased, e.g. for being able to provide smaller and smaller pixel sizes. In some processes, masks are used for defining the pixels when the evaporated material passes through the mask openings. However, shadowing effects of a mask, the spread of the evaporated material and the like make it difficult to further increase the precision and the predictability of the evaporation process.

In view of the above, it is an object of embodiments described herein to provide a material deposition arrangement, a vacuum deposition system, and a method for depositing material on a substrate that overcomes at least some of the problems in the art.

### SUMMARY OF THE INVENTION

In light of the above, a material deposition arrangement, a vacuum deposition system, and a method for depositing material on a substrate according to the independent claims are provided.

According to one embodiment, a material deposition arrangement for depositing evaporated material on a substrate in a vacuum chamber is provided. The material deposition arrangement may include a crucible for providing material to be evaporated; and a linear distribution pipe being in fluid communication with the crucible. The material deposition arrangement may further include a plurality of nozzles in the distribution pipe for guiding the evaporated material into the vacuum chamber. Each nozzle may have a nozzle inlet for receiving the evaporated material, a nozzle outlet for releasing the evaporated material to the vacuum chamber, and a nozzle passage between the nozzle inlet and the nozzle outlet. According to embodiments described herein, the nozzle passage of at least one of the plurality of nozzles includes a first section having a first section length and a first section size, and a second section having a second section length and a second section size. The ratio of the second section size to the first section size is between 2 and 10.

According to a further embodiment, a vacuum deposition system is provided. The vacuum deposition system includes a vacuum deposition chamber, and a material deposition arrangement according to embodiments described herein in the vacuum chamber. The vacuum deposition system further includes a substrate support for supporting the substrate during deposition.

According to a further embodiment, a method for depositing a material on a substrate in a vacuum deposition chamber is provided. The method includes evaporating a material to be deposited in a crucible; and providing the evaporated material to a linear distribution pipe being in fluid communication with the crucible. The distribution pipe typically is at a first pressure level. The method further includes guiding the evaporated material through a nozzle in the linear distribution pipe to the vacuum deposition chamber: The vacuum deposition chamber may provide a second pressure level different from the first pressure level. Guiding the evaporated material through the nozzle includes guiding the evaporated material through a first section of the nozzle having a first section length and a first section size, and guiding the evaporated material through a second section having a second section length and a second section size, wherein the ratio of the second section size to the first section size is between 2 and 10.

Embodiments are also directed at apparatuses for carrying out the disclosed methods and include apparatus parts for performing each described method step. The method steps may be performed by way of hardware components, a computer programmed by appropriate software, by any combination of the two or in any other manner. Furthermore, embodiments are also directed at methods for operating the described apparatus. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIGS. 1a to 1e show schematic views of embodiments of a nozzle for a material deposition arrangement according to embodiments described herein;

FIG. 2a shows a diagram of the material distribution of a material deposition arrangement according to embodiments described herein;

FIG. 2b shows a diagram of the material distribution of a deposition arrangement of a known system;

FIGS. 3a to 3c show a material deposition arrangement according to embodiments described herein;

FIG. 4 shows a schematic side view of a material deposition arrangement according to embodiments described herein;

FIG. 5 shows a vacuum deposition system according to embodiments described herein;

FIGS. 6a and 6b show schematic views of distribution pipes and nozzles of a material deposition arrangement according to embodiments described herein; and

FIG. 7 shows a flow chart of a method for depositing material on a substrate according to embodiments described herein.

### DETAILED DESCRIPTION OF EMBODIMENTS

Reference will now be made in detail to various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

As used herein, the term “fluid communication” may be understood in that two elements being in fluid communication can exchange fluid via a connection, allowing fluid to flow between the two elements. In one example, the elements being in fluid communication may include a hollow structure, through which the fluid may flow. According to some embodiments, at least one of the elements being in fluid communication may be a pipe-like element.

Furthermore, in the following description, a material deposition arrangement or material source arrangement (both terms may be used synonymously herein) may be understood as an arrangement (or source) providing a material to be deposited on a substrate. In particular, the material deposition arrangement may be configured for providing material to be deposited on a substrate in a vacuum chamber, such as a vacuum deposition chamber or system. According to some embodiments, the material deposition arrangement may provide the material to be deposited on the substrate in being configured to evaporate the material to be deposited. For instance, the material deposition arrangement may include an evaporator or a crucible, which evaporates the material to be deposited on the substrate, and a distribution pipe, which, in particular, releases the evaporated material in a direction towards the substrate, e.g. through an outlet or a nozzle.

According to some embodiments described herein, a distribution pipe may be understood as a pipe for guiding and distributing the evaporated material. In particular, the distribution pipe may guide the evaporated material from the evaporator to the outlet (such as nozzles or openings) in the distribution pipe. A linear distribution pipe may be understood as a pipe extending in a first, especially longitudinal, direction. In some embodiments, the linear distribution pipe includes a pipe having the shape of a cylinder, wherein the cylinder may have a circular bottom shape or any other suitable bottom shape.

A nozzle as referred to herein may be understood as a device for guiding a fluid, especially for controlling the direction or characteristics of a fluid (such as the rate of flow, speed, shape, and/or the pressure of the fluid that emerges from the nozzle). According to some embodiments described herein, a nozzle may be a device for guiding or directing a vapor, such as a vapor of an evaporated material to be deposited on a substrate. The nozzle may have an inlet for receiving a fluid, a passage (e.g. a bore or opening for guiding the fluid through the nozzle), and an outlet for releasing the fluid. According to embodiments described herein, the passage or opening of the nozzle may include a defined geometry for achieving the direction or characteristic of the fluid flowing through the nozzle. According to some embodiments, a nozzle may be part of a distribution pipe or may be connected to a distribution pipe providing evaporated material and may receive evaporated material from the distribution pipe.

According to embodiments described herein, a material deposition arrangement for depositing evaporated material on a substrate in a vacuum chamber is provided. The material deposition arrangement may include a crucible for providing material to be evaporated and a linear distribution pipe being in fluid communication with the crucible. In one example, the crucible may be a crucible for evaporating organic materials, e.g. organic materials having an evaporation temperature of about 100° C. to about 600° C. Further, the material deposition arrangement includes a plurality of nozzles in the distribution pipe for guiding the evaporated material into the vacuum chamber. Each nozzle may have a nozzle inlet for receiving the evaporated material, a nozzle outlet for releasing the evaporated material to the vacuum chamber, and a nozzle passage between the nozzle inlet and the nozzle outlet. According to embodiments described herein, the nozzle passage of at least one of the plurality of nozzles includes a first section having a first length and a first size, and a second section having a second length and a second size. The ratio of the second section size to the first section size is typically between 2 and 10, more typically between 3 and 8, and even more typically between 3 and 7. In one example, the ratio of the second size to the first size may be 4.

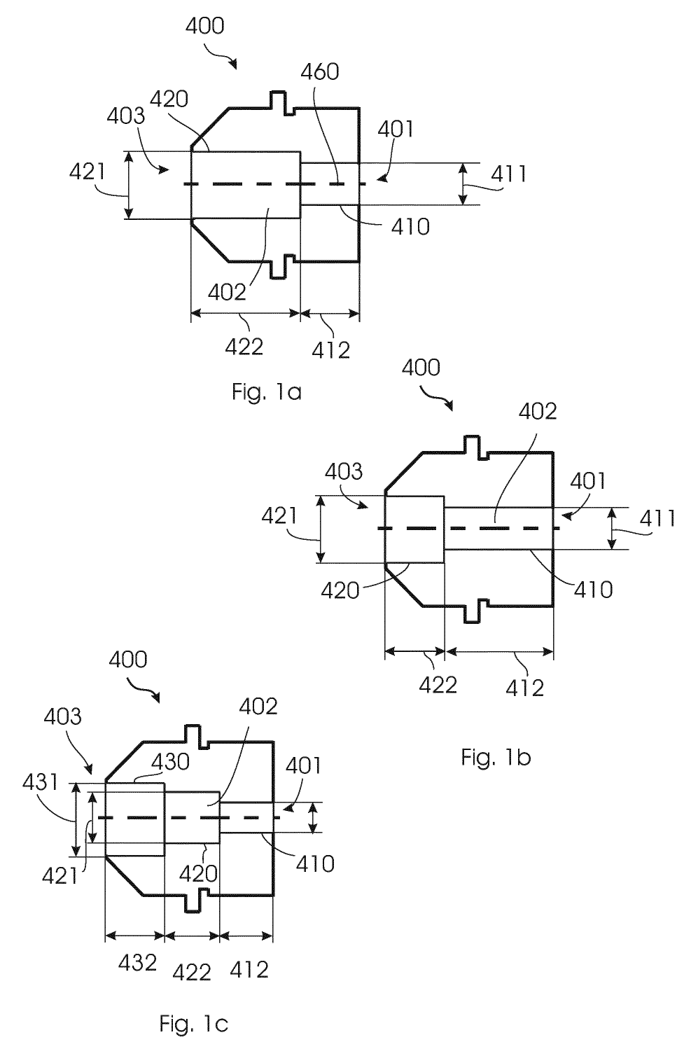

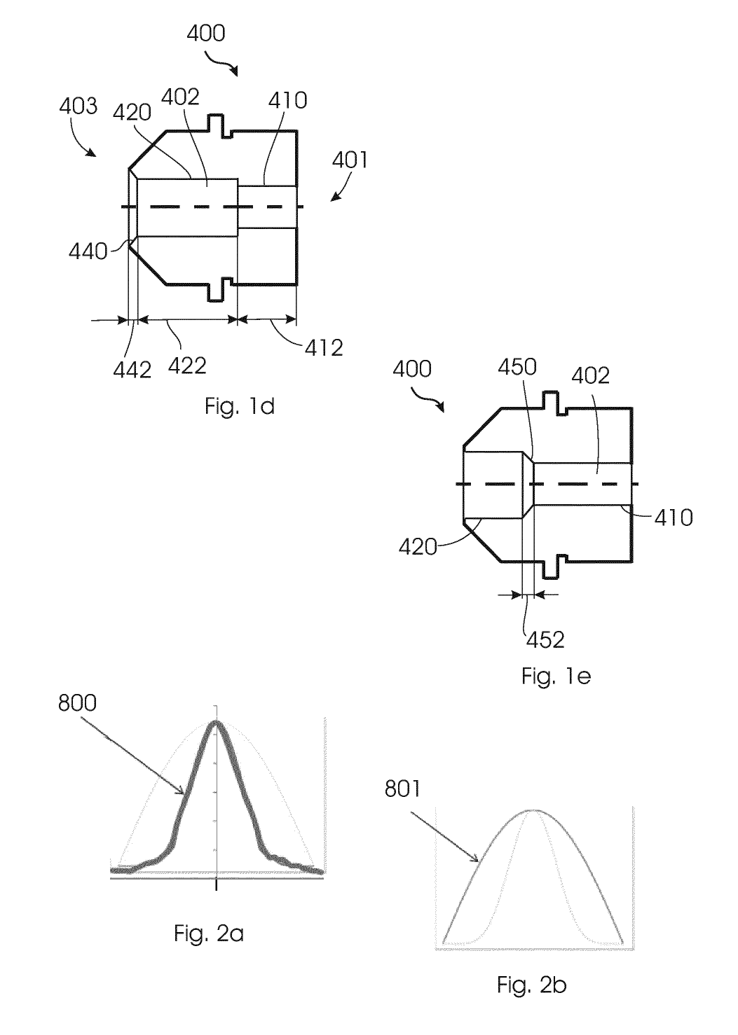

FIGS. 1a to 1e show examples of nozzles, which may be used in a material deposition arrangement according to embodiments described herein. All examples of nozzle 400 show a nozzle inlet 401, a nozzle outlet 403, and a passage 402 between the nozzle inlet 401 and the nozzle outlet 403. According to some embodiments, the evaporated material coming from the crucible is guided in the distribution pipe and enters the nozzle through the nozzle inlet. The evaporated material than passes through the nozzle passage 402 and exits the nozzle at the nozzle outlet 403. The flow direction of the evaporated material can be described as running from the nozzle inlet 401 to the nozzle outlet 403.

FIG. 1a shows a nozzle 400 with a first section 410 and a second section 420. The first section 410 of the nozzle 400 provides a first section size 411 and a first section length 412. The second section 420 of the nozzle 400 provides a second section size 421 and a second section length 422. According to embodiments described herein, the second section size may typically be between 2 to 10 times larger than the first section size, more typically between 2 and 8 times larger, and even more typically between 3 and 7 times larger. In one example, the second section size may be 4 times larger than the first section size.

According to some embodiments described herein, a section size of a nozzle may be understood as the size of a section of the nozzle passage (or opening). In one embodiment, the section size may be understood as being one dimension of the section, which is not the section length. According to some embodiments, the section size may be the minimum dimension of the cross-section of the nozzle section. For example, a circular shaped nozzle section may have a size being the diameter of the section. According to some embodiments described herein, the section length of a section of a nozzle may be understood as the dimension of the section along the length direction of the nozzle, or along the main flow direction of the evaporated material in the nozzle.

In some embodiments, which may be combined with other embodiments described herein, the first section of a nozzle may include the nozzle inlet. In some embodiments, which may be combined with other embodiments described herein, the second section of a nozzle may include the nozzle outlet. According to some embodiments, the size of the first section may typically be between 1.5 mm and about 8 mm, more typically between about 2 mm and about 6 mm, and even more typically between about 2 mm and about 4 mm. According to some embodiments, the size of the second section may be between 3 mm and about 20 mm, more typically between about 4 mm and about 15 mm, and even more typically between about 4 mm and about 10 mm. According to some embodiments, which may be combined with other embodiments described herein, the length of a nozzle section as described herein may typically be between 2 mm and about 20 mm, more typically between about 2 mm and about 15 mm, and even more typically between about 2 mm and about 10 mm. In one example, the length of one of the nozzle section may be about 5 mm to about 10 mm.

According to some embodiments, the mass flow within a nozzle used in a material deposition system according to embodiments described herein may typically be less than 1 sccm, more typically only a fractional amount of 1 sccm, and even more typically below 0.5 sccm. In one example, the mass flow in a nozzle according to embodiments described herein may be less than 0.1 sccm, such as 0.05 or 0.03 sccm. In some embodiments, the pressure in the distribution pipe, and at least partially in the nozzle may typically be between about 10−² mbar and 10⁻⁵ mbar, and more typically between about 10⁻² mbar and 10⁻³ mbar. The skilled person will understand that the pressure in the nozzle according to embodiments described herein may depend on the position within the nozzle, and may especially be between the above described pressure of the distribution pipe and the pressure present in the vacuum chamber, in which the material deposition arrangement according to embodiments described herein may be located. Typically, the pressure in a vacuum chamber, in which the material deposition arrangement according to embodiments described herein may be located, may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

According to some embodiments, the first section may be configured to increase the uniformity of the evaporated material guided from the distribution pipe into the nozzle, especially by having a smaller size than the second section, or by generally having a smaller size when compared to the diameter of the distribution pipe. According to some embodiments, the diameter of the distribution pipe may typically be between about 70 mm and about 120 mm, more typically, between about 80 mm and about 120 mm, and even more typically, between about 90 mm and about 100 mm. In some embodiments described herein (e.g. in the case of a distribution pipe having a substantially triangular like shape as explained in detail below), the above described values for the diameter may refer to the hydraulic diameter of the distribution pipe. According to some embodiments, the comparatively narrow first section may force the particles of the evaporated material to arrange in a more uniform manner. Making the evaporated material more uniform in the first section may for instance include making the density of the evaporated material, the velocity of the single particles and/or the pressure of the evaporated material more uniform. The skilled person may understand that in a material deposition arrangement according to embodiments described herein, such as a material deposition arrangement for evaporating organic materials, the evaporated material flowing in the distribution pipe and the nozzle (or parts of the nozzle) may be considered as a Knudsen flow. In particular, the evaporated material may be considered as a Knudsen flow in view of the above examples of flow and pressure conditions in the distribution pipe and the nozzle. According to some embodiments described herein, the flow in a portion of the nozzle (such as a portion being close to or adjacent to the nozzle outlet) may be a molecular flow. For instance, the second section of the nozzle according to embodiments described herein may provide a transition between a Knudsen flow and a molecular flow. In one example, the flow within the vacuum chamber, but outside of the nozzle, may be a molecular flow. According to some embodiments, the flow in the distribution pipe may be considered as being a viscous flow or a Knudsen flow. In some embodiments, the nozzle may be described as providing a transition from the Knudsen flow or viscous flow to the molecular flow.

According to embodiments described herein, the second section (being typically arranged adjacent to the first section) may be configured for increasing the directionality of the evaporated material. For instance, the evaporated material flowing from the first section to the second section will spread when leaving the first section which has a smaller size than the second section. The second section, however, may catch the evaporated material spreading from the first section and direct the evaporated material towards the substrate. When comparing the plume of evaporated material from a material deposition arrangement according to embodiments described herein to a plume of evaporated material of known systems, the plume is more precisely directed towards the substrate, or towards a mask (e.g. a pixel mask), as will be explained in detail below with respect to FIGS. 2a and 2b.

The material deposition arrangement according to embodiments described herein allows for a more precisely formed plume of evaporated material to be released from the nozzle. In particular, the spread of the particles of the evaporated material in the first section is captured and directed by the second section of the nozzle. Further, according to some embodiments described herein, the different sections of the nozzle provide a relatively gentle and stepwise transition between the different pressure levels in the distribution pipe of the material deposition arrangement and the vacuum deposition chamber, in which the material deposition arrangement may be placed. The gentle pressure transition allows for controlling the flow of evaporated material in an improved manner.

Going to FIGS. 2a and 2b, the effect of the nozzle of the material deposition arrangement according to embodiments described herein can be seen and compared to a known material deposition system. In FIG. 2a, test data of the distribution of evaporated material as released from a material deposition arrangement according to embodiments described herein is shown. The curve 800 shows the experimental result of an evaporated material released from a nozzle having a first section and a second section as described above. The example of FIG. 2a shows that the distribution of evaporated material follows approximately a cos¹⁰ like shape. According to some embodiments, the material distribution of the material deposition arrangement may have a shape corresponding approximately to a cos¹² like shape or even cos¹⁴ like shape. In detail, the distribution of the evaporated material released from a nozzle of a material deposition arrangement according to embodiments described herein may correspond to the above named cos-shapes only with regard to an upper part. For instance, the shown curve does not cross the zero line as a cosinus curve would do. The curve may be described as following the Clausing formula. The comparison with a known material deposition arrangement as shown in FIG. 2b shows that the distribution of conventional material deposition arrangements corresponds to a cos¹ shape as shown by curve 801. According to some embodiments, the curve of a nozzle of a known deposition system may also achieve cos⁵ or cos⁶ like shapes. The difference between the curve 800 generated by a material deposition arrangement according to embodiments described herein and the curve 801 of known systems is substantially the width of the plume of evaporated material and the concentration distribution of the evaporated material in the plume. For example, if masks are used for depositing material on a substrate, such as in an OLED production system, the mask may be a pixel mask with pixel openings having the size of about 50 μm×50 μm, or even below, such as a pixel opening with a dimension of the cross section (e.g. the minimum dimension of a cross section) of about 30 μm or less, or about 20 μm. In one example, the pixel mask may have a thickness of about 40 μm. Considering the thickness of the mask and the size of the pixel openings, a shadowing effect may appear, where the walls of the pixel openings in the mask shadow the pixel opening. The material deposition arrangement according to embodiments described herein may help in reducing the shadowing effect.

Gas flow simulations of the material deposition arrangement according to embodiments described herein show that the herein described nozzle design is able to concentrate material deposition on a substrate on a small area of +/−30 degree (or +/−20 degree) (looking from the nozzle in the direction of the material (gas) flow to the substrate). In the special case of the deposition of e.g. Alq3 for OLED manufacturing, the small area may be considered as one factor to form a high pixel density (dpi) on a display.

The high directionality, which can be achieved by using the evaporation with a material deposition arrangement according to embodiments described herein, further leads to an improved utilization of the evaporated material, because more of the evaporated material actually reaches the substrate (and, for instance, not the area above and below the substrate).

Going back to FIGS. 1a to 1e, different embodiments for reaching the above described effects can be seen. FIG. 1a was already discussed in detail above. FIG. 1b shows a nozzle 400 as may be used in a material deposition arrangement according to embodiments described herein. The nozzle 400 includes a first section 410 and a second section 420. In the example shown in FIG. 1b, the first section includes the nozzle inlet 401. The shown example further shows the second section 420 including the nozzle outlet 403. However, this is only an example and does not limit the nozzle design. The first section 410 has a smaller first section size 411 than the second section 420 having a second section size 421. In the embodiment shown in FIG. 1b, the first section length 412 is larger than the second section length 422. In an alternative embodiment, as can be seen in FIG. 1a, the first section length 412 is smaller than the second section length 422. According to a further example, the first section length and the second section length may have substantially the same, or similar, length.

FIG. 1c shows a nozzle 400 as may be used in a material deposition arrangement according to embodiments described herein. The nozzle 400 of FIG. 1c includes a first section 410 having a first section size 411 and a first section length 412, a second section 420 having a second section size 421 and a second section length 422, and a third section 430 having a third section size 431 and a third section length 432. In the embodiment shown in FIG. 1c, the third section size 431 is larger than the second section size 421, and the second section size 421 is larger than the first section size 411. For instance, the ratio between the third section size 431 and second section size 421 and/or the ratio between second section size and first section size may typically be between about 1.5 to about 10, more typically between about 1.5 and 8, and even more typically between about 2 and 6.

In the embodiment shown in FIG. 1c, the third section 430 includes the nozzle outlet 403. As shown in the example of FIG. 1c, the first section 410 includes the nozzle inlet. According to some embodiments, the nozzle may include further sections, such as n sections being adjacently arranged. Typically, each of the n sections may provide a larger size than the preceding section, when going in a direction from the nozzle inlet to the nozzle outlet. In one example, n is typically larger than 2, more typically larger than 3.

According to some embodiments described herein, the section(s) being located nearer to the nozzle outlet (or sections including the nozzle outlet) may have a larger section size than the section(s) being located nearer to the nozzle inlet (or sections including the nozzle inlet). For instance, a center point of the nozzle in the longitudinal direction of the nozzle (shown as axis 460 in FIG. 1a and omitted in the following figures for the sake of a better overview) may be a reference for the section located nearer to the nozzle inlet or the nozzle outlet.

FIG. 1d shows an embodiment of a nozzle 400 as may be used in a material deposition arrangement according to embodiments described herein, and which may be combined with other embodiments described herein. The example of a nozzle 400 shown in FIG. 1d includes a first section 410 having a first section length 412, a second section 420 having a second section length 422, and a fringe section 440 having a fringe section length 442. All sections may have a section size measured as indicated in FIGS. 1a to 1c. The fringe section 440 may typically be located at the nozzle outlet 403. According to some embodiments, the fringe section 440 may have different fringe section sizes along the fringe section length 442. For instance, the fringe section size may be smaller at a first end of the fringe section 440 being adjacent to another section (e.g. the second section 420) than at a second end of the fringe section at the nozzle outlet 403. In the sectional view of FIG. 1d, the fringe section 440 provides tapered walls. In one embodiment, the shape of the fringe section 440 may be described as being funnel like or cap like. According to some embodiments, the length of the fringe section 440 may be equal to or smaller than the length of the first and/or the second section. In one example, the length of the fringe section may typically be between ⅙ and ⅔ of the first and/or second section length.

The skilled person may understand that other embodiments of the nozzle for a material deposition arrangement according to embodiments described herein may be equipped with a fringe section as exemplarily shown in FIG. 1d.

FIG. 1e shows an embodiment, which may be combined with other embodiments described herein. The nozzle 400, which may be used in a material deposition arrangement according to embodiments described herein, includes a first section 410 and a second section 420. The first section and the second section may be sections as described above having section sizes and section lengths. The example shown in FIG. 1e further includes a transitional section 450 being located between the first section 410 and the second section 420. The transitional section 450 typically provides a smooth transition between the first section 410 and the second section 420. When comparing the example of FIG. 1e to the examples shown in FIGS. 1a to 1d, it can be seen that the examples of FIGS. 1a to 1d show step like transitions between different sections. The example of FIG. 1d provides a slope between the different sections using transitional section 450. According to some embodiments, the size of the transitional section 452 may range from the first section size to the second section size. In some embodiments, the transitional section length 452 may be any suitable length for a transitional section. For instance, the transitional section length 452 may be similar to the section lengths of the first and/or the second section, or may be a fraction of the length of the first and/or the second section. In one example, the length of the transitional section may typically be between ⅙ and 4/6, more typically between ⅙ and ½ and even more typically between ⅓ and ½ of the first and/or second section length. The skilled person may understand that a transitional section may be used between any sections of a nozzle described herein and is not limited to the configuration shown in FIG. 1e.

According to some embodiments described herein, the nozzle (in particular the different nozzle sections) may provide an increasing conductance value with increasing distance to the nozzle inlet. For instance, each section may provide at least one conductance value, wherein the conductance value is the larger the nearer the section is to the nozzle outlet. As an example (and not limited to the particular embodiment), the second section 420 of FIG. 1a may have a higher conductance value than the first section 410, wherein the first section precedes the second section in a direction from the nozzle inlet to the nozzle outlet. According to some embodiments, each section provides a lower pressure level (than the preceding section when seen in a direction from the nozzle inlet to the nozzle outlet) with decreasing distance of the section to the nozzle outlet. According to some embodiments, the conductance value may be measured in l/s. In one example, the flow within the nozzle being below 1 sccm may also be described as being below 1/60 mbar l/s. In some embodiments, the section size may be chosen so as to provide an increasing conductance value of each section with decreasing distance to the nozzle outlet. According to some embodiments described herein, a section may provide a typically larger or substantially equal conductance value than the preceding section in a direction from the nozzle inlet to the nozzle outlet.

According to some embodiments, the shape of the nozzle passage may be any suitable shape for guiding evaporated material through the nozzle. For instance, the cross-section of the nozzle passage may have a substantially circular shape, but may also have an elliptical shape, or the shape of an elongated hole. In some embodiments, the cross-section of the nozzle passage may have a substantially rectangular, a substantially quadratic, or even a substantially triangular shape.

The term “substantially” as used herein may mean that there may be a certain deviation from the characteristic denoted with “substantially.” Typically, a deviation of about 15% of the dimensions or the shape of the characteristic denoted with “substantially” may be possible. For instance, the term “substantially circular” refers to a shape which may have certain deviations from the exact circular shape, such as a deviation of about 1 to 15% or 10% of the general extension in one direction, if suitable. In some embodiments, a value may be described with “substantially.” The skilled person may understand that the value described with “substantially” may have a deviation of about 1% to about 10% or 15% from the named value.

According to some embodiments, which may be combined with other embodiments described herein, the first section and the second section of the nozzle may be integrally formed in the nozzle. For instance, the nozzle may be formed as one piece including the first section and the second section. According to some embodiments, the nozzle does not provide extra parts for providing the first section and the second section. In some embodiments, the nozzle may be made from one piece of material having differently sized holes, e.g. bore holes. The skilled person may understand that the nozzle, even though described as being a one piece nozzle in some embodiments, may provide a coating on the outer and/or inner surface, such as a coating with material being chemically inert to evaporated organic materials.

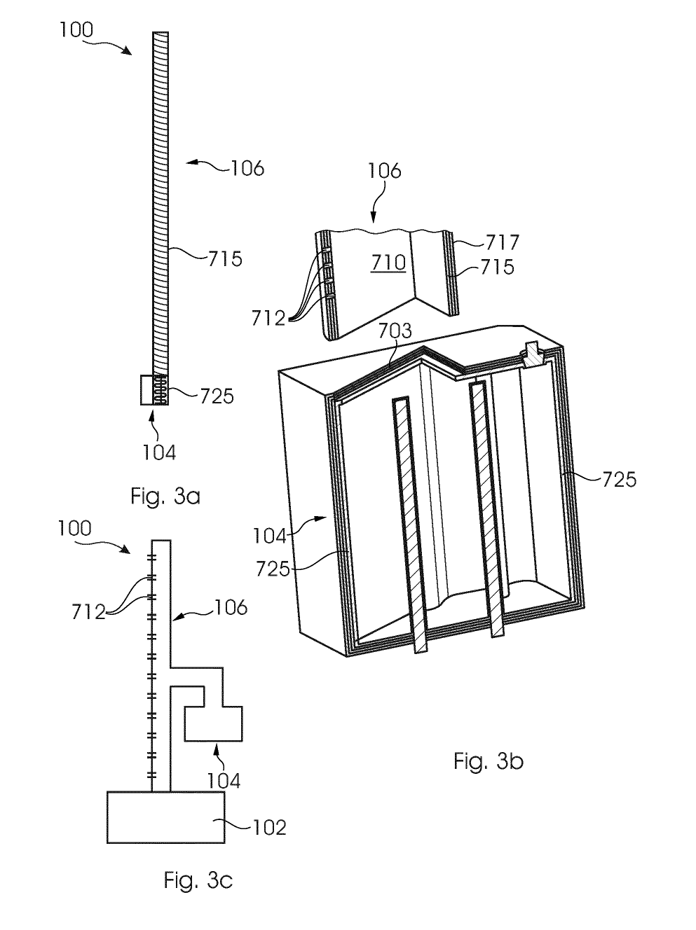

FIGS. 3a to 3c show a material deposition arrangement 100 according to embodiments described herein. A material deposition arrangement may include a distribution pipe 106 and an evaporation crucible 104 as an evaporator as shown in FIG. 3a. The distribution pipe 106 may stand in fluid communication with the crucible for distributing evaporated material provided by the crucible 104. The distribution pipe can for example be an elongated cube with heating unit 715. The evaporation crucible can be a reservoir for the organic material to be evaporated with a heating unit 725. According to typical embodiments, which can be combined with other embodiments described herein, the distribution pipe 106 provides a line source. According to some embodiments described herein, the material deposition arrangement 100 further includes a plurality of nozzles 712 for releasing the evaporated material towards the substrate, e.g. nozzles being arranged along at least one line. According to some embodiments, the nozzles 712, used for the material deposition arrangement of FIGS. 3a to 3c, may be nozzles as described with respect to FIGS. 1a to 1e.

According to some embodiments, which can be combined with other embodiments described herein, the nozzles of the distribution pipe may be adapted for releasing the evaporated material in a direction different from the length direction of the distribution pipe, such as a direction being substantially perpendicular to the length direction of the distribution pipe. According to some embodiments, the nozzles are arranged to have a main evaporation direction being horizontal +−20°. According to some specific embodiments, the evaporation direction can be oriented slightly upward, e.g. to be in a range from horizontal to 15° upward, such as 3° to 7° upward. Correspondingly, the substrate can be slightly inclined to be substantially perpendicular to the evaporation direction. Undesired particle generation can be reduced. However, the nozzle and the material deposition arrangement according to embodiments described herein may also be used in a vacuum deposition system, which is configured for depositing material on a horizontally oriented substrate.

In one example, the length of the distribution pipe 106 corresponds at least to the height of the substrate to be deposited in the deposition system. In many cases, the length of the distribution pipe 106 will be longer than the height of the substrate to be deposited, at least by 10% or even 20%. A uniform deposition at the upper end of the substrate and/or the lower end of the substrate can be provided.

According to some embodiments, which can be combined with other embodiments described herein, the length of the distribution pipe can be 1.3 m or above, for example 2.5 m or above. According to one configuration, as shown in FIG. 3a, the evaporation crucible 104 is provided at the lower end of the distribution pipe 106. The organic material is evaporated in the evaporation crucible 104. The vapor of organic material enters the distribution pipe 106 at the bottom of the distribution pipe and is guided essentially sideways through the plurality of nozzles in the distribution pipe, e.g. towards an essentially vertical substrate.

FIG. 3b shows an enlarged schematic view of a portion of the material deposition arrangement, wherein the distribution pipe 106 is connected to the evaporation crucible 104. A flange unit 703 is provided, which is configured to provide a connection between the evaporation crucible 104 and the distribution pipe 106. For example the evaporation crucible and the distribution pipe are provided as separate units, which can be separated and connected or assembled at the flange unit, e.g. for operation of the material deposition arrangement.

The distribution pipe 106 has an inner hollow space 710. A heating unit 715 may be provided to heat the distribution pipe. Accordingly, the distribution pipe 106 can be heated to a temperature such that the vapor of the organic material, which is provided by the evaporation crucible 104, does not condense at an inner portion of the wall of the distribution pipe 106. For instance, the distribution pipe may be held at a temperature, which is typically about 1° C. to about 20° C., more typically about 5° C. to about 20° C., and even more typically about 10° C. to about 15° C. higher than the evaporation temperature of the material to be deposited on the substrate. Two or more heat shields 717 are provided around the tube of the distribution pipe 106.

During operation, the distribution pipe 106 may be connected to the evaporation crucible 104 at the flange unit 703. The evaporation crucible 104 is configured to receive the organic material to be evaporated and to evaporate the organic material. According to some embodiments, the material to be evaporated may include at least one of ITO, NPD, Alq₃, Quinacridone, Mg/AG, starburst materials, and the like.

As described herein, the distribution pipe can be a hollow cylinder. The term cylinder can be understood as having a circular bottom shape, a circular upper shape and a curved surface area or shell connecting the upper circle and the little lower circle. According to further additional or alternative embodiments, which can be combined with other embodiments described herein, the term cylinder can further be understood in the mathematical sense as having an arbitrary bottom shape, an identical upper shape and a curved surface area or shell connecting the upper shape and the lower shape. Accordingly, the cylinder does not necessarily need to have a circular cross-section. Instead, the base surface and the upper surface can have a shape different from a circle.

FIG. 4 shows a material deposition arrangement 100 according to embodiments described herein. The material deposition arrangement includes two evaporators 102a and 102b, and two distribution pipes 106a and 106b standing in fluid communication with the evaporators 102a and 102b. The material deposition arrangement further includes nozzles 712 in the distribution pipes 106a and 106b. The nozzles 712 may be nozzles as described above with respect to FIGS. 1a to 1e. The nozzles 712 of the first distribution pipes have a longitudinal direction 210, which may correspond to the axis 460 of the nozzle 400 exemplarily shown in FIG. 1a. According to some embodiments, the nozzles 712 may have a distance between each other. In some embodiments, the distance between the nozzles 712 may be measured as the distance between the longitudinal directions 210 of the nozzles. According to some embodiments, which may be combined with other embodiments described herein, the distance between the nozzles may typically be between about 10 mm and about 50 mm, more typically between about 10 mm and about 40 mm, and even more typically between about 10 mm and about 30 mm. According to some embodiments described herein, the above described distances between the nozzles may be useful for the deposition of organic materials through a pixel mask, such as a mask having an opening size of 50 μm×50 μm, or even less, such as a pixel opening with a dimension of the cross section (e.g. the minimum dimension of a cross section) of about 30 μm or less, or about 20 μm. In some embodiments, the second section size of the nozzles may be chosen dependent on the distance between the nozzles. For instance, if the distance between the nozzles is 20 mm, the second section size of the nozzle (or the section size of a section including the nozzle outlet, or the section having the largest size of the sections in the nozzle) may be up to 15 mm, or less. According to some embodiments, the distance between the nozzles may be used for determining the ratio of the second section size to the first section size.

According to some embodiments, a vacuum deposition system is provided. The vacuum deposition system includes a vacuum chamber and a material deposition arrangement as exemplarily described above in embodiments. The vacuum deposition system further includes a substrate support for supporting the substrate during deposition. In the following, an example of a vacuum deposition system according to embodiments described herein is described.

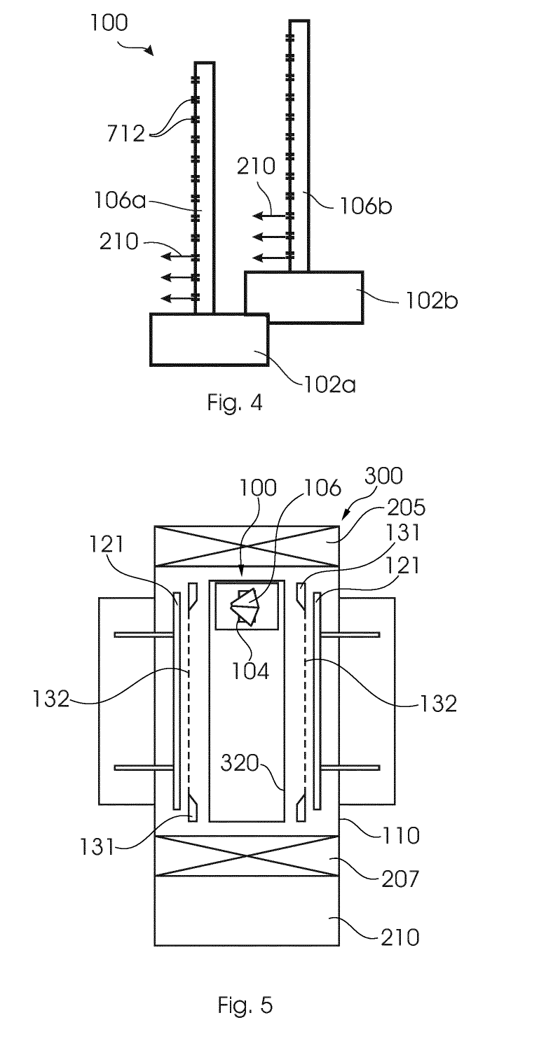

FIG. 5 shows a vacuum deposition system 300 in which a material deposition arrangement or a nozzle according to embodiments described herein may be used. The deposition system 300 includes a material deposition arrangement 100 in a position in a vacuum chamber 110. According to some embodiments, which can be combined with other embodiments described herein, the material deposition arrangement is configured for a translational movement and a rotation around an axis. The material deposition arrangement 100 has one or more evaporation crucibles 104 and one or more distribution pipes 106. Two evaporation crucibles and two distribution pipes are shown in FIG. 5. Two substrates 121 are provided in the vacuum chamber 110. Typically, a mask 132 for masking of the layer deposition on the substrate can be provided between the substrate and the material deposition arrangement 100. Organic material is evaporated from the distribution pipes 106. According to some embodiments, the material deposition arrangement may include a nozzle as shown in FIGS. 1a to 1e. In one example, the pressure in the distribution pipe may be between about 10⁻² mbar to about 10⁻⁵ mbar, or between about 10⁻² to about 10⁻³ mbar. According to some embodiments, the vacuum chamber may provide a pressure of about 10⁻⁵ to about 10⁻⁷ mbar.

According to embodiments described herein, the substrates are coated with organic material in an essentially vertical position. The view shown in FIG. 5 is a top view of a system including the material deposition arrangement 100. Typically, the distribution pipe is a vapor distribution showerhead, particularly a linear vapor distribution showerhead. The distribution pipe provides a line source extending essentially vertically. According to embodiments described herein, which can be combined with other embodiments described herein, essentially vertically is understood particularly when referring to the substrate orientation, to allow for a deviation from the vertical direction of 20° or below, e.g. of 10° or below. The deviation can be provided for example because a substrate support with some deviation from the vertical orientation might result in a more stable substrate position. Yet, the substrate orientation during deposition of the organic material is considered essentially vertical, which is considered different from the horizontal substrate orientation. The surface of the substrates is typically coated by a line source extending in one direction corresponding to one substrate dimension and a translational movement along the other direction corresponding to the other substrate dimension. According to other embodiments, the deposition system may be a deposition system for depositing material on an essentially horizontally oriented substrate. For instance, coating of a substrate in a deposition system may be performed in an up or down direction.

FIG. 5 illustrates an embodiment of a deposition system 300 for depositing organic material in a vacuum chamber 110. The material deposition arrangement 100 is movable within the vacuum chamber 110, such as by a rotational or a translational movement. The material source shown in the example of FIG. 5 is arranged on a track, e.g. a looped track or linear guide 320. The track or the linear guide 320 is configured for the translational movement of the material deposition arrangement 100. According to different embodiments, which can be combined with other embodiments described herein, a drive for the translational or rotational movement can be provided in the material deposition arrangement 100 within the vacuum chamber 110 or a combination thereof. FIG. 5 shows a valve 205, for example a gate valve. The valve 205 allows for a vacuum seal to an adjacent vacuum chamber (not shown in FIG. 5). The valve can be opened for transport of a substrate 121 or a mask 132 into the vacuum chamber 110 or out of the vacuum chamber 110.

According to some embodiments, which can be combined with other embodiments described herein, a further vacuum chamber, such as maintenance vacuum chamber 210 is provided adjacent to the vacuum chamber 110. Typically, the vacuum chamber 110 and the maintenance vacuum chamber 210 are connected with a valve 207. The valve 207 is configured for opening and closing a vacuum seal between the vacuum chamber 110 and the maintenance vacuum chamber 210. The material deposition arrangement 100 can be transferred to the maintenance vacuum chamber 210 while the valve 207 is in an open state. Thereafter, the valve can be closed to provide a vacuum seal between the vacuum chamber 110 and the maintenance vacuum chamber 210. If the valve 207 is closed, the maintenance vacuum chamber 210 can be vented and opened for maintenance of the material deposition arrangement 100 without breaking the vacuum in the vacuum chamber 110.

Two substrates 121 are supported on respective transportation tracks within the vacuum chamber 110 in the embodiment shown in FIG. 5. Further, two tracks for providing masks 132 thereon are provided. Coating of the substrates 121 can be masked by respective masks 132. According to typical embodiments, the masks 132, i.e. a first mask 132 corresponding to a first substrate 121 and a second mask 132 corresponding to a second substrate 121, are provided in a mask frame 131 to hold the mask 132 in a predetermined position.

The described material deposition arrangement may be used for various applications, including applications for OLED device manufacturing including processing steps, wherein two or more organic materials are evaporated simultaneously. Accordingly, as for example shown in FIG. 5, two distribution pipes and corresponding evaporation crucibles can be provided next to each other.

Although the embodiment shown in FIG. 5 provides a deposition system with a movable source, the skilled person may understand that the above described embodiments may also be applied in deposition systems in which the substrate is moved during processing. For instance, the substrates to be coated may be guided and driven along stationary material deposition arrangements.

Embodiments described herein particularly relate to deposition of organic materials, e.g. for OLED display manufacturing on large area substrates. According to some embodiments, large area substrates or carriers supporting one or more substrates may have a size of at least 0.174 m². For instance, the deposition system may be adapted for processing large area substrates, such as substrates of GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. According to typical embodiments, which can be combined with other embodiments described herein, the substrate thickness can be from 0.1 to 1.8 mm and the holding arrangement for the substrate, can be adapted for such substrate thicknesses. However, particularly the substrate thickness can be about 0.9 mm or below, such as 0.5 mm or 0.3 mm, and the holding arrangements are adapted for such substrate thicknesses. Typically, the substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

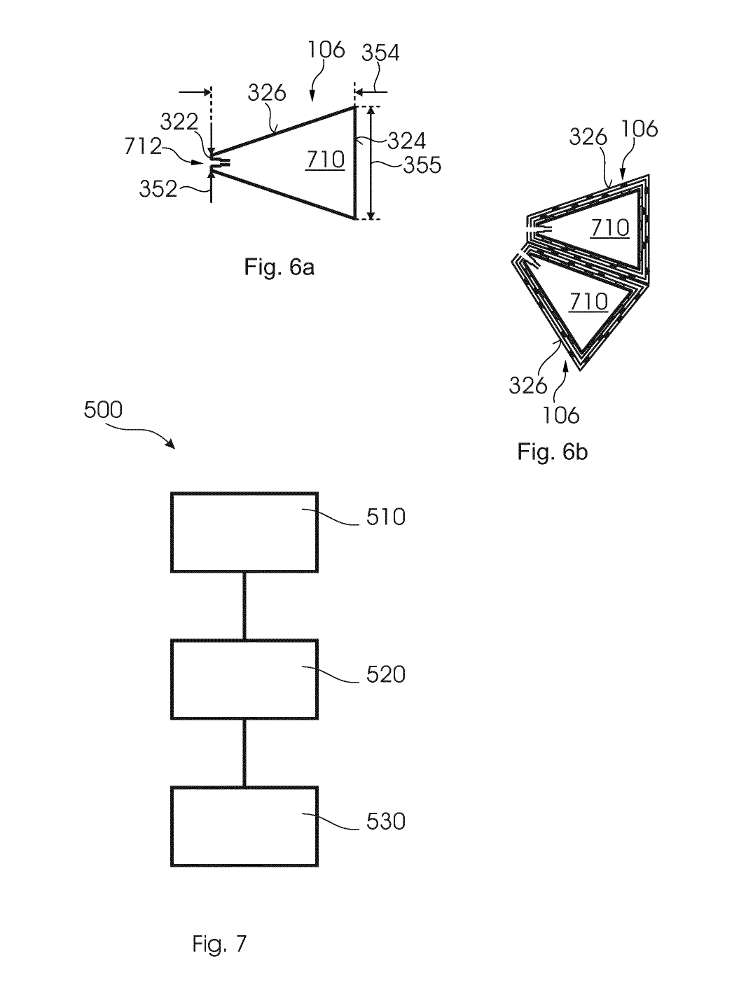

According to some embodiments, which may be combined with other embodiments described herein, the distribution pipe of the material deposition arrangement according to embodiments described herein may have a substantially triangular cross-section. FIG. 6a shows an example of a cross-section of a distribution pipe 106. The distribution pipe 106 has walls 322, 326, and 324, which surround an inner hollow space 710. The wall 322 is provided at an outlet side of the material source, at which the nozzles 712 are provided. The cross-section of the distribution pipe can be described as being essentially triangular, that is the main section of the distribution pipe corresponds to a portion of a triangle and/or the cross-section of the distribution pipe can be triangular with rounded corners and/or cut-off corners. As shown in FIG. 6a, for example the corner of the triangle at the outlet side is cut off.

The width of the outlet side of the distribution pipe, e.g. the dimension of the wall 322 in the cross-section shown in FIG. 6a, is indicated by arrow 352. Further, the other dimensions of the cross-section of the distribution pipe 106 are indicated by arrows 354 and 355. According to embodiments described herein, the width of the outlet side of the distribution pipe is 30% or less of the maximum dimension of the cross-section, e.g. 30% of the larger dimension of the dimensions indicated by arrows 354 and 355. In light of the dimensions and the shape of the distribution pipe, the nozzles 712 of neighboring distribution pipes 106 can be provided at a smaller distance. The smaller distance improves mixing of organic materials, which are evaporated next to each other.

FIG. 6b shows an embodiment where two distribution pipes are provided next to each other. Accordingly, a material deposition arrangement having two distribution pipes as shown in FIG. 6b can evaporate two organic materials next to each other. As shown in FIG. 6b, the shape of the cross-section of the distribution pipes 106 allows for placing nozzles of neighboring distribution pipes close to each other. According to some embodiments, which can be combined with other embodiments described herein, a first nozzle of the first distribution pipe and a second nozzle of the second distribution pipe can have a distance of 30 mm or below, such as from 5 mm to 25 mm. More specifically, the distance of the first outlet or nozzle to a second outlet or nozzle can be 10 mm or below.

According to some embodiments, a method for depositing material on a substrate may be provided. A flowchart 500 illustrates a method according to embodiments described herein. With method 500, a material may be deposited on a substrate in a vacuum deposition chamber. According to some embodiments, the vacuum deposition chamber may be a vacuum deposition chamber as described in embodiments above, e.g. with respect to FIG. 5. In box 510, the method 500 includes evaporating a material to be deposited in a crucible. For instance, the material to be deposited may be an organic material for forming an OLED device. The crucible may be heated depending on the evaporation temperature of the material. In some examples, the material is heated up to 600° C., such as heated up to a temperature between about 100° C. and 600° C. According to some embodiments, the crucible stands in fluid communication with a distribution pipe. In box 520, the evaporated material is provided to a linear distribution pipe being in fluid communication with the crucible. Typically, the distribution pipe is at a first pressure level. In one example, the first pressure level is typically between about 10⁻² mbar to 10⁻⁵ mbar, more typically between about 10⁻² mbar and 10⁻³ mbar.

In some embodiments, the material deposition arrangement is configured to move the evaporated material using only the vapor pressure of the evaporated material in a vacuum, i.e. the evaporated material is driven to the distribution pipe (and/or through the distribution pipe) by the evaporation pressure only (e.g. by the pressure originating from the evaporation of the material). For instance, no further means (such as fans, pumps, or the like) are used for driving the evaporated material to and through the distribution pipe. The distribution pipe typically includes several outlets or nozzles for guiding the evaporated material to the vacuum chamber, in which the deposition takes place, or in which the material deposition arrangement is located during operation.

According to some embodiments, the method includes in box 530 guiding the evaporated material trough a nozzle in the linear distribution pipe to the vacuum deposition chamber providing a second pressure level. In some embodiments, the second pressure level may be between about 10⁻⁵ to 10⁻⁷ mbar. According to some embodiments, guiding the evaporated material through the nozzle includes guiding the evaporated material through a first section of the nozzle having a first section length and a first section size, and guiding the evaporated material through a second section having a second section length and a second section size, wherein the ratio of the second size to the first size is between 2 and 10. In one example, the ratio of the second size to the first size is about 4. According to some embodiments, the nozzle may be a nozzle as described in embodiments above, such as the embodiments shown and described in FIGS. 1a to 1e.

According to some embodiments, the method may further include influencing the uniformity of the evaporated material in the first section of the nozzle and influencing the directionality of the evaporated material released to the vacuum chamber by the second section of the nozzle. The ratio of the section sizes may help to increase the uniformity of the evaporated material and the directionality of the evaporated material. For instance, the smaller size of the first section, which the evaporated material passes at first, may force the evaporated material to an increased uniformity, e.g. regarding the material density, the material velocity, and/or the material pressure. According to some embodiments described herein, the second section may increase the directionality by capturing the evaporated material spreading from the smaller cross-section of the first section when leaving the first section. The evaporated material may be reach the substrate or pixel mask with a small spreading angle.

The nozzle contour used in a material deposition arrangement according to embodiments described herein may focus the material flow of an evaporated material to the substrate. The nozzle according to embodiments described herein is used to focus evaporated material in the gaseous phase from an evaporator source to a substrate within a vacuum chamber, e.g. for generating an OLED active layer on a substrate.

According to some embodiments, the described nozzle design in a material deposition arrangement according to embodiments described herein provides a smaller, in particular cylindrical section, and a larger, in particular cylindrical section, wherein the larger section is directed towards the substrate, or the outlet of the nozzle. Experimental results of the material deposition arrangement according to embodiments described herein show a +17% higher material concentration on a substrate in a +/−30 degree area and a +23% higher material concentration on a substrate in a +/−20 degree area. The absorption peak in the center opposite to the nozzle could be about 40% higher compared to a nozzle as known with a single cylindrical nozzle. The improvement compared to known systems is very effectual and could not be achieved by design changes as usually done in a simple cylindrical nozzle.

According to some embodiments, the use of a material deposition arrangement as described herein, and/or the use of a vacuum deposition system as described herein is provided.

While the foregoing is directed to some embodiments, other and further embodiments may be devised without departing from the basic scope thereof, and the scope thereof is determined by the claims that follow.

1. A material deposition arrangement for depositing evaporated material on a substrate in the vacuum chamber, comprising:
a crucible for providing material to be evaporated;
a linear distribution pipe in fluid communication with the crucible; and
a plurality of nozzles in the distribution pipe for guiding the evaporated material into the vacuum chamber, each nozzle having a nozzle inlet for receiving the evaporated material, a nozzle outlet for releasing the evaporated material to the vacuum chamber, and a nozzle passage between the nozzle inlet and the nozzle outlet,
wherein the nozzle passage of at least one of the plurality of nozzles comprises a first section having a first length and a first size, and a second section having a second length and a second size, wherein the ratio of the second size to the first size is between 2 and 10.

2. The material deposition arrangement according to claim 1, wherein the first section (410) is configured for increasing the uniformity of the evaporated material and the second section is configured for increasing the directionality of the evaporated material.

3. The material deposition arrangement according to claim 1, wherein the first section and the second section are integrally formed in the nozzle.

4. The material deposition arrangement according to claim 1, wherein the size of the first section and the second section is defined by the minimum dimension of the cross-section of the respective section.

5. The material deposition arrangement according to claim 1, wherein the material deposition arrangement is configured for a mass flow of evaporated material of less than 1 seem.

6. The material deposition arrangement according to claim 1, wherein the nozzle passage comprises n sections, wherein each of the sections has a larger size than the preceding section in a direction from the nozzle inlet to the nozzle outlet.

7. The material deposition arrangement according to claim 1, wherein each section provides an equal or larger conductance value than the preceding section in a direction from the nozzle inlet to the nozzle outlet.

8. The material deposition arrangement according to claim 1, wherein the first section comprises the inlet of the nozzle and/or wherein the second section comprises the outlet of the nozzle.

9. The material deposition arrangement according to claim 1, wherein the material deposition arrangement is configured for depositing one or more organic materials on the substrate.

10. A vacuum deposition system, comprising:
a vacuum deposition chamber;
a material deposition arrangement comprising:
a crucible for providing material to be evaporated;
a linear distribution pipe in fluid communication with the crucible;
a plurality of nozzles in the distribution pipe for guiding the evaporated material into the vacuum chamber, each nozzle having a nozzle inlet for receiving the evaporated material, a nozzle outlet for releasing the evaporated material to the vacuum chamber, and a nozzle passage between the nozzle inlet and the nozzle outlet, wherein the nozzle passage of at least one of the plurality of nozzles comprises a first section having a first length and a first size, and a second section having a second length and a second size, wherein the ratio of the second size to the first size is between 2 and 10; and
a substrate support for supporting the substrate in the vacuum deposition chamber during deposition.

11. The vacuum deposition system chamber according to claim 10, wherein the vacuum deposition chamber further comprises a pixel mask between the substrate support and the material deposition arrangement.

12. The vacuum deposition system chamber according to claim 10, wherein the distribution pipe of the material deposition arrangement provides a first pressure level and the vacuum chamber provides a second pressure level different from the first pressure level, wherein the first size of the first section of the nozzle and the second size of the second section of the nozzle provide a transition between the first pressure level in the distribution pipe and the second pressure level in the vacuum chamber.

13. The vacuum deposition system according to claim 10, wherein the vacuum deposition system is adapted for simultaneously housing two substrates to be coated on two substrate supports within the vacuum deposition chamber, and wherein the material deposition arrangement is arranged movably between the two substrate supports within the vacuum deposition chamber, the crucible of the material deposition arrangement being a crucible for evaporating organic material.

14. A method for depositing a material on a substrate in a vacuum deposition chamber, comprising:
evaporating a material to be deposited in a crucible;
providing the evaporated material to a linear distribution pipe being in fluid communication with the crucible, the distribution pipe at a first pressure level; and
guiding the evaporated material through a nozzle in the linear distribution pipe to the vacuum deposition chamber providing a second pressure level different from the first pressure level, wherein guiding the evaporated material through a nozzle comprises guiding the evaporated material through a first section of the nozzle having a first length and a first size, and guiding the evaporated material through a second section having a second section length and a second size, wherein the ratio of the second size to the first size is between 2 and 10.

15. The method according to claim 14, further comprising influencing the uniformity of the evaporated material in the first section of the nozzle and influencing the directionality of the evaporated material released to the vacuum deposition chamber by the second section of the nozzle.

16. The material deposition arrangement according to claim 2, wherein the first section and the second section are integrally formed in the nozzle.

17. The material deposition arrangement according to claim 1, wherein the first length and the second length have the same, or similar, length.

18. The material deposition arrangement according to claim 1, wherein the length of at least one of the first section and the second section is between 5 mm and 10 mm.

19. The vacuum deposition system according to claim 13, wherein the pixel mask comprises openings of less than 50 μm.

20. The vacuum deposition system according to claim 19, wherein a first pressure level in the linear distribution pipe is between 10⁻² mbar and 10⁻³ mbar and a second pressure level in the vacuum deposition chamber is between 10⁻⁵ mbar and 10⁻⁷ mbar.
